(19) United States
(12) Patent Application Publication
(10) Pub. No.: US 2026/0239957 A1
(43) Pub. Date: Aug. 13, 2026

(54) POWER SEMICONDUCTOR MODULE INCLUDING COOLING STRUCTURE

(71) Applicants: HYUNDAI MOTOR COMPANY, SEOUL (KR); KIA CORPORATION, SEOUL (KR)

(72) Inventors: Hidekazu Tanisawa, Yokohama-Shi (JP); Ju Man Yoon, Hwaseong-si (KR)

(73) Assignees: HYUNDAI MOTOR COMPANY, SEOUL (KR); KIA CORPORATION, SEOUL (KR)

(21) Appl. No.: 19/256,932

(22) Filed: Jul. 1, 2025

(30) Foreign Application Priority Data
Feb. 10, 2025 (JP) 2025-020343

(51) Int. Cl. H10W 40/10; H10W 40/25; H10W 40/73; H10W 90/00

(52) U.S. Cl. CPC H10W 40/10; H10W 40/259; H10W 40/73; H10W 90/00

(57) ABSTRACT

A power semiconductor module includes a first semiconductor device on one side, a second semiconductor device connected to the first semiconductor device in parallel, disposed to be spaced apart from the first semiconductor device, having a non-operating mode and having a heating value lower than that of the first semiconductor device, and a heat dissipation member commonly covering the first semiconductor device and the second semiconductor device, wherein the heat dissipation member includes an extension portion extending in a direction, different from the direction in which the first semiconductor device and the second semiconductor device are arranged, and when the second semiconductor device is in the non-operating mode, heat of the first semiconductor device is transported to the second semiconductor device through the extension portion.

### CROSS REFERENCE TO RELATED APPLICATIONS

This application claims benefit of priority to Japanese Patent Application No. 2025-020343 filed on February 10, 2025, in the Japanese Intellectual Property Office, the disclosure of which is incorporated herein by reference in its entirety.

### BACKGROUND

### Technical Field

The present disclosure relates to a power semiconductor module including a cooling structure, and more particularly, to a power semiconductor module in which semiconductor devices having different heating values are connected in parallel and heat from one semiconductor device with a small heating value may be transported to the other non-operating semiconductor device.

### Description of the Related Art

A power semiconductor module is equipped with a plurality of semiconductor devices, and a cooling system is designed to dissipate heat occurring at the maximum power. Semiconductor devices mounted in the power semiconductor module include SiC-MOSFETs (MOS-type electrolytic effect transistors on SiC substrates) and Si-IGBTs (insulated gate-type bipolar transistors on Si substrates). Si-IGBTs incur low costs and are easy to manufacture into devices with larger power capacities but have higher losses compared to SiC-MOSFETs.

### SUMMARY

When an adjacent semiconductor device is not generating heat, it is desirable to dissipate heat toward a corresponding region. By utilizing the region of the semiconductor device in which heat is not being generated as a heat dissipation path, the temperature of the semiconductor device may be lowered. By lowering the temperature, the loss of the semiconductor device may be reduced.

An aspect of the present disclosure is to provide a power semiconductor module, including a cooling structure capable of heat-transporting heat to one semiconductor device with a small heating value toward the other non-operating semiconductor device.

According to an aspect of the present disclosure, a power semiconductor module includes: a first semiconductor device on one side; a second semiconductor device connected to the first semiconductor device in parallel, disposed to be spaced apart from the first semiconductor device, having a non-operating mode and having a heating value lower than that of the first semiconductor device; and a heat dissipation member commonly covering the first semiconductor device and the second semiconductor device, wherein the heat dissipation member includes an extension portion extending in a direction, different from the direction in which the first semiconductor device and the second semiconductor device are arranged, and when the second semiconductor device is in the non-operating mode, the heat of the first semiconductor device is transported to the second semiconductor device through the extension portion.

The first semiconductor device may be a SiC-MOSFET, which is constantly operated, and the second semiconductor device may be a Si-IGBT.

The heat dissipation member may be a vapor chamber transporting heat by circulating an operating fluid.

The heat dissipation member may include graphite.

### BRIEF DESCRIPTION OF THE FIGURES

The above and other aspects, features, and advantages of the present disclosure will be more clearly understood from the following detailed description, taken in conjunction with the accompanying drawings, in which:

FIG. 1 is a front view illustrating a power semiconductor module equipped with a plurality of semiconductor devices and a cooling structure according to an embodiment of the present disclosure;

FIG. 2 is a cross-sectional view taken along line A-A of FIG. 1;

FIG. 3 is a configuration diagram of a vapor chamber;

FIG. 4 is a cross-sectional view taken along line A-A of FIG. 3;

FIG. 5 is a diagram illustrating that heat of a first semiconductor device is transported toward a second semiconductor device, by a vaporized operating liquid; and

FIG. 6 is a diagram illustrating the flow of heat when both the first and the second semiconductor device generate heat.

### DETAILED DESCRIPTION

While the present disclosure may be modified in various ways and take on various alternative forms, specific embodiments thereof are illustrated in the drawings and described in detail below. However, it should be understood that there is no intent to limit the present disclosure to the particular forms disclosed, but on the contrary, the present disclosure covers all modifications, equivalents, and alternatives falling within the spirit and scope of the present disclosure.

It will be understood that although the terms “first,” “second,” etc. may be used herein to describe various elements, these elements should not be limited by these terms. These terms are only used to distinguish one element from another. For example, a first element could be termed a second element, and a second element could similarly be termed a first element without departing from the scope of the present disclosure. As used herein, the term “and/or” includes any and all combinations of one or more items listed in the associated list.

The terms used herein to describe embodiments of the present disclosure are not intended to limit the scope of the present disclosure. The articles “a” and “an” are singular in that they have a single referent, however the use of the singular form in the present document should not preclude the presence of more than one referent. In other words, elements of the present disclosure referred to in the singular may number one or more unless the context clearly indicates otherwise. It will be further understood that the terms “comprise,” “comprising,” “include,” and/or “including,” when used herein, specify the presence of stated features, numbers, steps, operations, elements, and/or components but do not preclude the presence or addition of one or more other features, numbers, steps, operations, elements, components, and/or groups thereof.

Unless defined in a different way, all the terms used herein, including technical and scientific terms, have the same meanings as understood by those skilled in the art to which the present disclosure pertains. Such terms, as defined in generally used dictionaries, should be construed to have the same meanings as those of the contexts of the related art, and unless clearly defined in the application, they should not be construed to have ideally or excessively formal meanings. In the description below, terms used in relation to directions are described based on the illustration in the drawing. Hereinafter, embodiments of the present disclosure will be described with reference to the accompanying drawings.

Hereinafter, a power semiconductor module and a cooling structure, according to an embodiment of the present disclosure, will be described in detail with reference to the accompanying drawings.

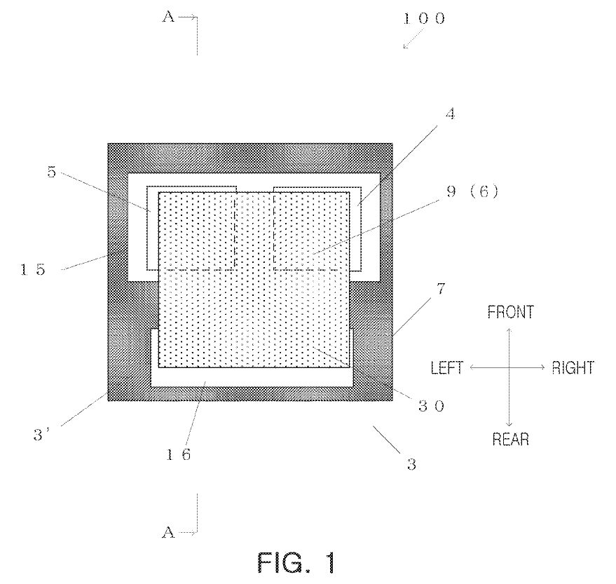

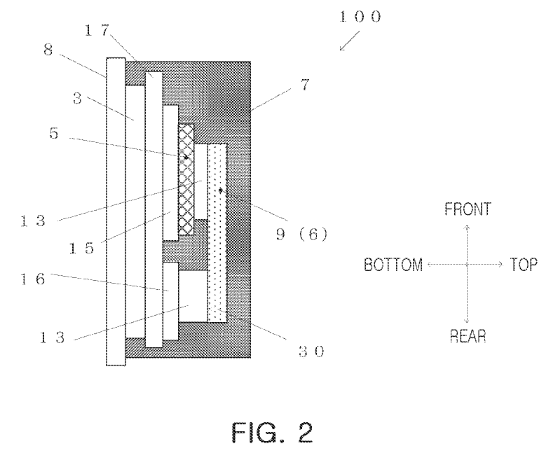

FIG. 1 is a front view illustrating a power semiconductor module 100 equipped with a plurality of semiconductor devices and a cooling structure according to an embodiment of the present disclosure. FIG. 2 is a cross-sectional view taken along line A-A of FIG. 1. The power semiconductor module 100 includes semiconductor devices connected in parallel to each other and a heat dissipation member 6 commonly covering the semiconductor devices.

In embodiment 1, a second semiconductor device is a Si-IGBT 4, and a first semiconductor device is a SiC-MOSFET 5. The Si-IGBT 4 is an insulated gate bipolar transistor formed on a silicon (Si) substrate, and the SiC-MOSFET 5 is a metal oxide electrolytic effect transistor formed on a silicon carbide (SiC) substrate. The Si-IGBT 4 is a transistor having a positive electrode terminal of a collector C, a negative electrode terminal of an emitter E, and a control terminal of a gate G. The SiC-MOSFET 5 is a transistor having a positive electrode terminal of a drain D, a negative electrode terminal of a source S, and a control terminal of a gate G. A heating value of the Si-IGBT 4 which uses a bipolar is greater than that of the SiC-MOSFET 5.

The Si-IGBT 4 and SiC-MOSFET 5 are connected in parallel and used. That is, the positive and negative electrode terminals are connected in parallel. The parallel-connected circuit is provided between, for example, a motor and a DC power supply and supplies current to the motor. When the motor load is small, the SiC-MOSFET 5 is used, and the Si-IGBT 4 is in a non-operating mode. When the motor load is large, both the SiC-MOSFET 5 and the Si-IGBT 4 are used simultaneously. The SiC-MOSFET 5 is constantly operated.

As illustrated in FIG. 1, in the power semiconductor module 100 of embodiment 1, the Si-IGBT 4 and the SiC-MOSFET 5 connected in parallel and arranged to be apart from each other horizontally. Therefore, the power semiconductor module 100 has a width in the horizontal direction, and the positive electrode terminal and the negative electrode terminal (not illustrated) are arranged in a front-rear direction. In embodiment 1, the heat dissipation member 6 is a flat-plate-shaped vapor chamber 9 and has an operating liquid 19 in an internal space thereof and performs cooling by repeating vaporization by heat and liquefaction by heat dissipation. The vapor chamber 9 is provided to commonly cover upper portions of the Si-IGBT 4 and SiC-MOSFET 5, and one side thereof in the front-rear direction extends to become an extension portion 30.

As illustrated in FIG. 2, one side of the vapor chamber 9 extends to become the extension portion 30. The extension portion 30 extends in a direction different from the direction in which the Si-IGBT 4 and the SiC-MOSFET 5 are arranged. The SiC-MOSFET 5 is bonded to a lower portion of the vapor chamber 9 via a bonding layer 13. A power layer 16 is bonded to the extension portion 30 of the vapor chamber 9 via the bonding layer 13. A lower side of the power layer 15 is a ceramic substrate 17, and a lower side of the ceramic substrate 17 is a metal substrate 3, and the entirety thereof is covered with a sealing member 7. A cooling plate 8 is provided on the outer side of the metal substrate 3. The cooling plate 8 may be a water-cooling cooler or an air-cooling cooler. Heat transferred to the extension portion 30 of the vapor chamber 9 passes through the power layer 16 and moves to the cooling plate 8.

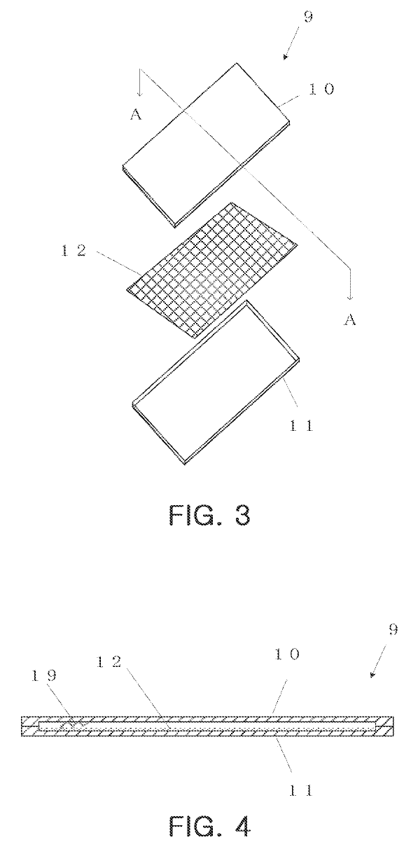

FIG. 3 is a configuration diagram of the vapor chamber 9 used as the heat dissipation member 6. FIG. 4 is a cross-sectional view taken along line A-A of FIG. 3. The vapor chamber 9 includes an upper cover 10 and a lower cover 11, has a rectangular flat plate shape, and a wick 12 corresponding to a capillary is placed an internal flat space thereof, and the operating liquid 19 is injected thereto. The operating liquid 19 is vaporized by external heat, moves in a direction toward a low pressure, and liquefied by heat dissipation. The liquefied operating liquid 19 returns to a heat source of the vapor chamber 9 through the wick 12. The vaporized operating liquid 19 may move in any direction, front, back, left, or right.

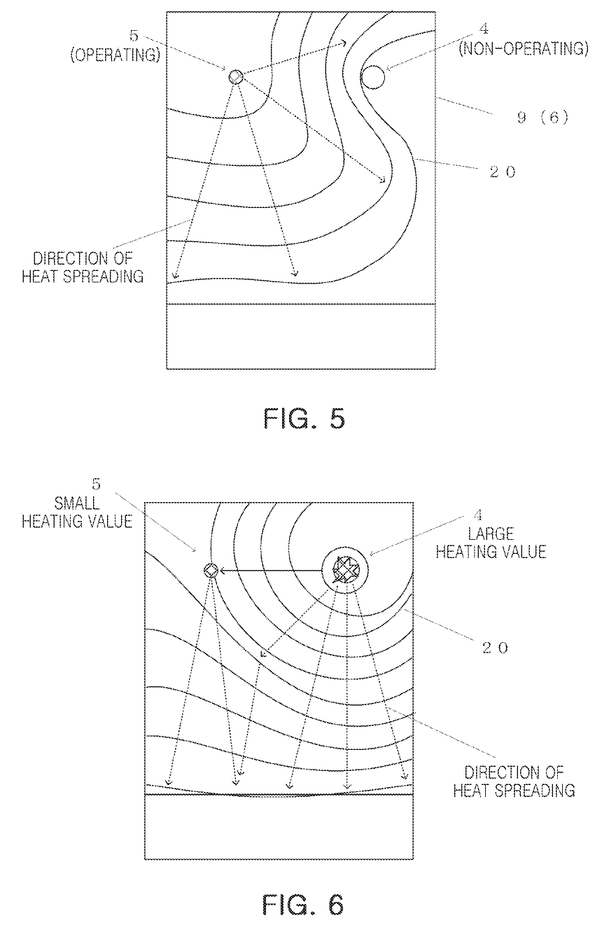

FIG. 5 is a diagram illustrating that heat of the SiC-MOSFET 5, a first semiconductor device, is transported to the non-operating Si-IGBT 4, a second semiconductor device, by a vaporized operating liquid. Since the Si-IGBT 4 is not generating heat due to non-operation, heat inside the vapor chamber 9 is dissipated mainly around the SiC-MOSFET 5. Heat of the SiC-MOSFET 5 is also efficiently and in large quantities transported toward the Si-IGBT 4. Heat is also transported to the extension portion 30 of the vapor chamber 9. As a result, the SiC-MOSFET 5 may be efficiently cooled. The isobaric lines 20 show an image in which the SiC-MOSFET 5 is at high pressure and the position of the Si-IGBT 4 and the position of the extension portion 30 are at low pressure. Accordingly, heat of the SiC-MOSFET 5 is transported to both the Si-IGBT 4 side and the extension portion 30 side. In contrast, in a structure in which the vapor chamber 9 is divided left and right to semiconductor devices of Si-IGBT 4 and SiC-MOSFET 5, it is not possible to perform cooling through the Si-IGBT 4.

FIG. 6 is a diagram illustrating flow of heat when both a second semiconductor device, Si-IGBT 4 and a first semiconductor device, SiC-MOSFET 5 generate heat. A temperature A of the Si-IGBT 4 is assumed to be about twice as large as a temperature B of the SiC-MOSFET 5. The isobaric line 20 may be drawn inside the vapor chamber 9, and a region in which the isobaric line is dense is a region in which heat transport is large. That is, a large heat transport may be performed from the Si-IGBT 4 on the upper right of FIG. 6 to the lower right. In addition, as the heating value of the Si-IGBT 4 is large, heat moves to the left area where the SiC-MOSFET 5 is located and is dissipated. Therefore, the Si-IGBT 4 is adjusted to promote heat dissipation more than the SiC-MOSFET 5, so that the temperature difference between the first and second semiconductor devices is reduced.

The heat dissipation member 6 may be formed of graphite in the shape of a flat plate instead of the vapor chamber 9. Graphite has high thermal conductivity. The thermal conductivity of graphite may decrease at high temperatures, compared to low temperatures thereof, but graphite may withstand use. Meanwhile, at high temperatures, the vapor chamber 9 has higher thermal conductivity than at low temperatures, so it is suitable for cooling semiconductor devices that become high in temperature.

In the above embodiment, the first semiconductor device with a small heating value and the second semiconductor device with a large heating value are the same size but without being limited thereto, and a plurality of semiconductor devices with different sizes may also be arranged. In addition, in the above embodiment, the areas of the semiconductor devices covered by the vapor chamber 9 are the same, but without being limited thereto, and the vapor chamber 9 may cover and contact different areas of the semiconductor devices. In the present embodiment, since cooling is performed using vaporization and liquefaction of the vapor chamber 9, it is preferable that the power semiconductor module be mounted in a vehicle in a vertical or horizontal arrangement with a heat source at the bottom.

In the power semiconductor module and the cooling structure according to an embodiment of the present disclosure, since the first semiconductor device with a small heating value and the second semiconductor device with a large heating value are mixed in one power semiconductor module, the maximum heating value of the power semiconductor module may be suppressed to a low level compared to a case in which only a semiconductor device with a large heating value is mounted.

Since a first semiconductor device may be a SiC-MOSFET, which is constantly operated (driven), and a second semiconductor device may be a Si-IGBT, which has an operating (driving) mode and a non-operating (non-driving) mode, heat from the first semiconductor device may be transported toward the second semiconductor device during the non-operating mode of the second semiconductor device.

Since the vapor chamber transporting heat by circulating an operating fluid is used as the heat dissipation member, heat may be transported in any direction, front, back, left, or right. Accordingly, heat from the SiC-MOSFET may be transported toward a cooled Si-IGBT while the Si-IGBT is not in operation, and thus, the temperature of the SiC-MOSFET may be lowered.

Since a graphite plate formed of graphite is used in the heat-dissipating member, heat from the SiC-MOSFET may be transported toward the cooled Si-IGBT while the Si-IGBT is not in operation.

While embodiments have been illustrated and described above, it will be apparent to those skilled in the art that modifications and variations could be made without departing from the scope of the present disclosure as defined by the appended claims.

1. A power semiconductor module comprising:
a first semiconductor device on a first side;
a second semiconductor device connected to the first semiconductor device in parallel, positioned spaced apart from the first semiconductor device, and having
an operating mode and a non-operating mode; and
a heat dissipation member covering the first semiconductor device and the second semiconductor device;
wherein the heat dissipation member includes a second portion extending in a second direction, different from a first direction in which the first semiconductor device and the second semiconductor device are arranged; and
wherein when the second semiconductor device is in the non-operating mode, heat from the first semiconductor device is transported to the second semiconductor device through the second portion.

2. The power semiconductor module of claim 1, wherein the first semiconductor device is a SiC-MOSFET which is constantly operated, and the second semiconductor device is a Si-IGBT having an operating mode and the non-operating mode.

3. The power semiconductor module of claim 1, wherein the heat dissipation member is a vapor chamber configured to transport heat by circulating an operating fluid.

4. The power semiconductor module of claim 3, wherein the vapor chamber comprises an upper cover, a lower cover, and a wick positioned between the upper cover and the lower cover.

5. The power semiconductor module of claim 3, wherein the operating fluid is vaporized by heat from an external source, is configured to move toward a region of low pressure and is liquefied as a result of heat dissipation.

6. The power semiconductor module of claim 1, wherein the first semiconductor device is configured to operate continuously, the second semiconductor device is configured to remain in the non-operating mode when the motor load is less than a predetermined value, and both the first semiconductor device and the second semiconductor device are configured to operate when the motor load is greater than the predetermined value.

7. The power semiconductor module of claim 1, wherein, during non-operation of the second semiconductor device, heat generated by the first semiconductor device is transported toward cooled regions of low pressure where the second semiconductor device is located and the second portion of the vapor chamber to dissipate the heat of the first semiconductor device.

8. The power semiconductor module of claim 1, wherein, when both the first semiconductor device and the second semiconductor device generate heat, and a second heating value of the second semiconductor device is larger than a first heating value of the first semiconductor device, the heat generated by the second semiconductor device is configured to move to an area where the first semiconductor device is located and is dissipated, to reduce a temperature difference between the first semiconductor device and the second semiconductor device and stabilize the power semiconductor module.

9. The power semiconductor module of claim 1, wherein the heat dissipation member includes graphite.
